(19) United States
(12) Patent Application Publication
(10) Pub. No.: US 2025/0374782 A1
(43) Pub. Date: Dec. 4, 2025

(54) DISPLAY APPARATUS

(71) Applicant: Samsung Display Co., Ltd., Yongin-si (KR)

(72) Inventors: Min KANG, Yongin-si (KR); Jaewon KIM, Yongin-si (KR); Hyungjun PARK, Yongin-si (KR); Hyunji CHA, Yongin-si (KR)

(21) Appl. No.: 19/096,689

(22) Filed: Mar. 31, 2025

(30) Foreign Application Priority Data
May 31, 2024 (KR) 10-2024-0071786

(51) Int. Cl. H10K 59/131; G09G 3/3233; G09G 3/3266

(52) U.S. Cl. CPC H10K 59/131; G09G 3/3233; G09G 3/3266; G09G 2300/0413; G09G 2300/0426; G09G 2300/0819; G09G 2300/0842; G09G 2300/0861; G09G 2310/0286

(57) ABSTRACT

A display apparatus includes a substrate including a display region and a peripheral region outside the display region, a display layer on the substrate, and a scan driver layer interposed between the substrate and the display layer, where, when viewed in a direction perpendicular to the substrate, the scan driver layer includes a scan driver which is located within a side portion of the display region next to an edge of the display region, and a dummy scan driver which is located at a center portion of the display region, and the dummy scan driver includes a dummy clock line extending in a first direction.

This application claims priority to Korean Patent Application No. 10-2024-0071786, filed on May 31, 2024, and all the benefits accruing therefrom under 35 U.S.C. § 119, the content of which in its entirety is herein incorporated by reference.

### BACKGROUND

### 1. Field

One or more embodiments relate to a display apparatus, and more specifically, to a display apparatus with a peripheral region having a reduced area and is capable of displaying high-quality images.

### 2. Description of the Related Art

In display apparatuses such as organic light-emitting display apparatuses, thin-film transistors are typically arranged in each subpixel to control the luminance of each subpixel. These thin-film transistors may control the luminance of the corresponding subpixel based on a transmitted data signal or the like.

A data signal may be transmitted to each subpixel via a data line in response to a signal from a scan driver located in a peripheral region outside a display region.

### SUMMARY

Such conventional display apparatuses may have a problem in that an area where a scan driver, etc. is located is large, or the quality of an image displayed in a display region deteriorates when the area where the scan driver, etc. is located is reduced.

One or more embodiments include a display apparatus with a peripheral region having a reduced area and is capable of displaying high-quality images.

According to one or more embodiments, a display apparatus includes a substrate including a display region and a peripheral region outside the display region, a display layer on the substrate, and a scan driver layer interposed between the substrate and the display layer, where, when viewed in a direction perpendicular to the substrate, the scan driver layer includes a scan driver which is located within a side portion of the display region next to an edge of the display region, and a dummy scan driver which is located at a center portion of the display region, and the dummy scan driver includes a dummy clock line extending in a first direction.

In an embodiment, the scan driver may extend in the first direction.

In an embodiment, the display layer may include a first display element and a first pixel circuit electrically connected to the first display element, and the dummy clock line may be electrically connected to the first pixel circuit.

In an embodiment, the display layer may include a first display element disposed over the dummy scan driver, and a first pixel circuit electrically connected to the first display element, the first pixel circuit may include a first wire extending in a second direction crossing the first direction, and the first wire may be electrically connected to the dummy clock line.

In an embodiment, the first wire and the dummy clock line may be electrically connected to a common electrode of the first display element.

In an embodiment, the first wire and the dummy clock line may be electrically connected to an initialization transistor of the first pixel circuit.

In an embodiment, the first wire and the dummy clock line may be electrically connected to a bias transistor of the first pixel circuit.

In an embodiment, the display layer may include a second display element disposed over the scan driver, and a second pixel circuit electrically connected to the second display element, the second pixel circuit may include a second wire extending in the second direction, and the second wire may be electrically connected to the first wire.

In an embodiment, the second wire and the first wire may be integrally formed as a single unitary indivisible body.

According to one or more embodiments, a display apparatus includes a substrate including a display region and a peripheral region outside the display region, a display layer on the substrate, and a scan driver layer interposed between the substrate and the display layer, where, when viewed in a direction perpendicular to the substrate, the scan driver layer includes a scan driver which is located within a side portion of the display region next to an edge of the display region, and dummy scan drivers which are located at a center portion of the display region, and the dummy scan drivers include dummy clock lines extending in a first direction.

In an embodiment, the scan driver may extend in the first direction.

In an embodiment, the display layer may include first display elements and first pixel circuits electrically connected to the first display elements, respectively, and the dummy clock lines may be electrically connected to the first pixel circuits.

In an embodiment, the display layer may include first display elements disposed over the dummy scan drivers, and first pixel circuits electrically connected to the first display elements, respectively, the first pixel circuits may include first wires extending in a second direction crossing the first direction and arranged in the first direction, and the first wires may be electrically connected to the dummy clock lines.

In an embodiment, each of the first wires may be electrically connected to the dummy clock lines.

In an embodiment, the first wires and the dummy clock lines may be electrically connected to a common electrode of the first display elements.

In an embodiment, the first wires and the dummy clock lines may be electrically connected to initialization transistors of the first pixel circuits.

In an embodiment, the first wires and the dummy clock lines may be electrically connected to bias transistors of the first pixel circuits.

In an embodiment, the display layer may include second display elements disposed over the scan driver, and second pixel circuits electrically connected to the second display elements, respectively, the second pixel circuits may include second wires arranged in the first direction and extending in the second direction, and each of the second wires may be electrically connected to a corresponding one of the first wires.

In an embodiment, each of the second wires and the corresponding one of the first wires may be integrally formed as a single unitary indivisible body.

In an embodiment, the display layer may include first display elements disposed over the dummy scan drivers, and first pixel circuits electrically connected to the first display elements, respectively, the first pixel circuits may include first first wires extending in a second direction crossing the first direction and arranged in the first direction, and second first wires extending in the second direction and arranged in the first direction, the first first wires may be electrically connected to a first group of the dummy clock lines, and the second first wires may be electrically connected to a second group of the dummy clock lines.

In an embodiment, the first first wires may be electrically connected to initialization transistors of the first pixel circuits, and the second first wires may be electrically connected to bias transistors of the first pixel circuits.

According to one or more embodiments, an electronic apparatus may include one of the display apparatuses described above.

In an embodiment, the electronic apparatus may be at least one of a smartphone, a mobile phone, a navigation device, a game device, a television (TV), a vehicle head unit, a notebook computer, a laptop computer, a tablet computer, a personal media player (PMP), or a personal digital assistant (PDA).

Features of embodiments other than those described above will become apparent from the following drawings, claims, and detailed descriptions to embody the disclosure below.

### BRIEF DESCRIPTION OF THE DRAWINGS

The above and other features of certain embodiments of the disclosure will be more apparent from the following description taken in conjunction with the accompanying drawings, in which:

FIG. 1 is a block diagram schematically showing an organic light-emitting display apparatus according to an embodiment;

FIG. 2 is a cross-sectional view schematically showing a portion of the display apparatus of FIG. 1;

FIG. 3 is a block diagram describing a scan driver included in the display apparatus of FIG. 1;

FIG. 4 is an equivalent circuit diagram of one pixel included in the display apparatus of FIG. 1;

FIG. 5 is a plan view schematically showing emission regions of a plurality of pixels included in the display apparatus of FIG. 1;

FIG. 6 is a plan view schematically showing positions of transistors, capacitors, etc. in pixels included in the display apparatus of FIG. 1;

FIGS. 7 to 13 are plan views schematically showing components, such as transistors and capacitors, of the display apparatus shown in FIG. 6, for each layer;

FIG. 14 is a plan view schematically showing a pixel electrode layer of the display apparatus shown in FIG. 6;

FIG. 15 is a cross-sectional view schematically showing cross-sections taken along lines A-A′ and B-B′ of FIG. 6;

FIG. 16 is a conceptual view schematically showing a connection relationship between wires included in the display apparatus of FIG. 1;

FIG. 17 is a conceptual view schematically showing a connection relationship between wires included in a display apparatus according to an embodiment;

FIG. 18 is a plan view schematically showing one layer included in a display apparatus according to an embodiment; and

FIG. 19 is a conceptual view schematically showing a connection relationship between wires included in the display apparatus of FIG. 18.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. In the description with reference to the drawings, the same or corresponding components are indicated by the same reference numerals and any repetitive detailed descriptions thereof may be omitted or simplified.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the following embodiment, it will be understood that when a component such as a layer, film, region, or plate is referred to as being “on” another layer, film, region, or plate, it can be directly or indirectly formed on the other layer, film, region, or plate. That is, for example, intervening layers, films, regions, or plates may be present. Also, sizes of components in the drawings may be exaggerated for convenience of explanation. In other words, since sizes and thicknesses of components in the drawings are arbitrarily illustrated for convenience of explanation, the following embodiments are not limited thereto.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It will be understood that when a layer, region, or component is referred to as being “connected to” another layer, area, or component, it can be directly or indirectly connected to the other layer, region, or component. That is, for example, intervening layers, regions, or components may be present. For example, in the present specification, when a layer, region, or component is electrically connected to another layer, region, or component, the layers, regions, or components may not only be directly electrically connected, but may also be indirectly electrically connected via another layer, region, or component therebetween.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

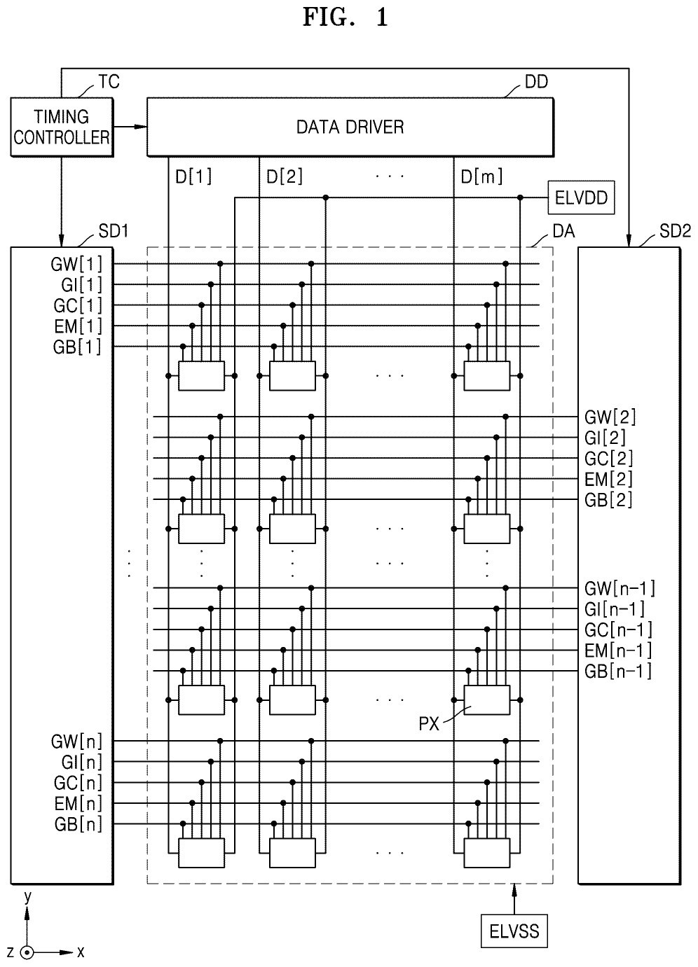

FIG. 1 is a block diagram schematically showing an organic light-emitting display apparatus according to an embodiment.

In one or more embodiments, an electronic apparatus may include the display apparatus described below. In other words, the organic light-emitting display apparatus according to an embodiment may be implemented as an electronic apparatus such as a smartphone, a mobile phone, a navigation device, a game device, a television (TV), a vehicle head unit, a notebook computer, a laptop computer, a tablet computer, a personal media player (PMP), or a personal digital assistant (PDA). In an embodiment, the electronic apparatus may be a flexible apparatus.

The organic light-emitting display apparatus according to an embodiment may include a display region DA including pixels PX, a first scan driver SD1, a second scan driver SD2, a data driver DD, a timing controller TC for controlling a scan driver SD and the data driver DD.

Each of the first scan driver SD1 and the second scan driver SD2 may have a shape extending in a first direction (y-axis direction). The first scan driver SD1 and the second scan driver SD2 may supply, under control by the timing controller TC, scan signals GW[1] to GW[n], initialization signals GI[1] to GI[n], compensation control signals GC[1] to GC[n], light-emission control signals EM[1] to EM[n], or bias control signals GB[1] to GB[n] to scan lines extending in a second direction (x-axis direction) crossing the first direction. In an embodiment, for example, the first scan driver SD1 and the second scan driver SD2 may sequentially supply the scan signals GW[1] to GW[n], the initialization signals GI[1] to GI[n], the compensation control signals GC[1] to GC[n], the light-emission control signals EM[1] to EM[n], and the bias control signals GB[1] to GB[n] to scan lines, initialization lines, compensation control lines, light-emission control lines, and bias control lines, respectively.

Each of the scan signals GW[1] to GW[n], the initialization signals GI[1] to GI[n], the compensation control signals GC[1] to GC[n], the light-emission control signals EM[1] to EM[n], and the bias control signals GB[1] to GB[n] may be a high voltage or a low voltage. Each transistor may be turned on when a high voltage is applied and may be turned off when a low voltage is applied, or may be turned off when a high voltage is applied and may be turned on when a low voltage is applied, according to characteristics thereof.

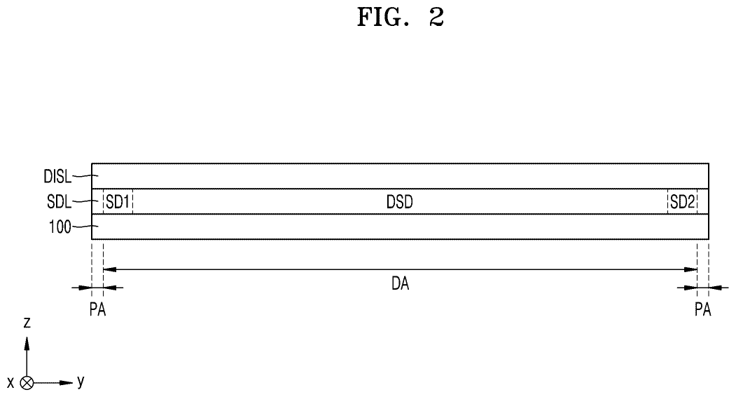

For reference, for convenience of illustration and description, FIG. 1 shows that the first scan driver SD1 is located on one side of the display region DA, and the second scan driver SD2 is located on an opposing side of the display region DA, but in practice, the first scan driver SD1 and the second scan driver SD2 may be located in the display region DA. In detail, when viewed in a direction (z-axis direction) perpendicular to a substrate 100 (see FIG. 2) included in a display apparatus, that is, in a plan view, the first scan driver SD1 and the second scan driver SD2 may be located in the display region DA. The first scan driver SD1 and the second scan driver SD2 may be located within the display region DA, and may be next to edges of the display region DA. In an embodiment, for example, the display region DA has, in a −x direction and a +x direction, edges extending in the first direction (y-axis direction), where the first scan driver SD1 may be located within the display region DA and may be adjacent to the edge which extends in the first direction (y-axis direction) and is located in the −x direction, and the second scan driver SD2 may be located within the display region DA and may be adjacent to the edge which extends in the first direction (y-axis direction) and is located in the +x direction.

The display apparatus according to an embodiment includes the first scan driver SD1 and the second scan driver SD2, and thus, when n is an odd number, the first scan driver SD1 may supply, to the pixels PX located in odd-numbered rows, the scan signals GW[1], GW[3], . . . , and GW[n], the initialization signals GI[1], GI[3], . . . , and GI[n], the compensation control signals GC[1], GC[3], . . . , and GC[n], the light-emission control signals EM[1], EM[3], . . . , and EM[n], or the bias control signals GB[1], GB[3], . . . , and GB[n], and the second scan driver SD2 may supply, to the pixels PX located in even-numbered rows, the scan signals GW[2], GW[4], . . . , and GW[n−1], the initialization signals GI[2], GI[4], . . . , and GI[n−1], the compensation control signals GC[2], GC[4], . . . , and GC[n−1], the light-emission control signals EM[2], EM[4], . . . , and EM[n−1], or the bias control signals GB[2], GB[4], . . . , and GB[n−1].

However, the disclosure is not limited thereto, and various modifications may be made. In another embodiment, for example, the first scan driver SD1 located on one side of the display region DA may supply the scan signals GW[1] to GW[n], etc. to the pixels PX located in all rows, and the second scan driver SD2 located on an opposing side of the display region DA may supply the light-emission control signals EM[1] to EM[n], etc. to the pixels PX located in all rows. Alternatively, only one scan driver located in the display region DA may be provided.

The data driver DD may supply data signals D[1] to D[m] to data lines extending in the first direction (y-axis direction) under control by the timing controller TC. The data driver DD may supply the data signals D[1] to D[m] to be synchronized with the scan signals GW[1] to GW[n], and accordingly, the data signals D[1] to D[m] may be supplied to the pixels PX selected by the scan signals GW[1] to GW[n].

The timing controller TC may control the first scan driver SD1, the second scan driver SD2, and the data driver DD based on synchronization signals supplied from an outside.

A power voltage ELVDD and an electrode voltage ELVSS may be supplied to the pixels PX in the display region DA. The pixels PX to which the power voltage ELVDD and the electrode voltage ELVSS have been supplied may generate light of luminance corresponding to the data signals D[1] to D[m] by controlling the amount of current flowing from a power voltage line to an electrode power line via an organic light-emitting diode in accordance with the data signals D[1] to D[m]. The power voltage ELVDD may be applied to the power voltage line, and the electrode voltage ELVSS may be applied to the electrode power line.

FIG. 1 shows an embodiment where, in the display region DA, the pixels PX are sequentially arranged in the first direction (y-axis direction) and the second direction (x-axis direction), but the disclosure is not limited thereto. In another embodiment, for example, the pixels PX may be arranged in various forms such as a pentile arrangement, a mosaic arrangement, etc. in addition to a stripe arrangement. In addition, the display region DA may appear to have a rectangular shape on a plan view as shown in FIG. 1, or alternatively, the display region DA may appear to have a polygonal shape such as a triangle, pentagon, or hexagon, or may appear to have a circular, elliptical, or irregular shape.

FIG. 2 is a cross-sectional view schematically showing a portion of the display apparatus of FIG. 1. As shown in FIG. 2, the display apparatus according to an embodiment includes the substrate 100, a display layer DISL, and a scan driver layer SDL.

The substrate 100 may include glass, a metal, or polymer resin. In an embodiment where a portion of the substrate 100 is bent, the substrate 100 may have flexible or bendable characteristics. In such an embodiment, the substrate 100 may include, for example, polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including two layers including polymer resin as described above and a barrier layer arranged therebetween and including an inorganic material (for example, silicon oxide, silicon nitride, or silicon oxynitride), and various modifications may be made.

The substrate 100 includes the display region DA and a peripheral region PA outside the display region DA. The display region DA is where an image is displayed, and a plurality of pixels may be arranged in the display region DA. When viewed in a direction (z-axis direction) approximately perpendicular to a display panel 10, the display region DA may have, for example, various shapes, such as a circle, an ellipse, a polygon, or a specific shape. The peripheral region PA may be located outside the display region DA.

The display layer DISL is disposed over the substrate 100, and the scan driver layer SDL is disposed between the substrate 100 and the display layer DISL. The display layer DISL may include display elements and pixel circuits electrically connected to the display elements. In an embodiment, for example, the display layer DISL may have, in a portion corresponding to one subpixel, one display element and a pixel circuit that is electrically connected to the display element and adjusts the luminance of light emitted from the display element.

The scan driver layer SDL includes the first scan driver SD1 and the second scan driver SD2 as described above, and also includes a dummy scan driver DSD. The dummy scan driver DSD is located in the display region DA when viewed in a direction (z-axis direction) perpendicular to the substrate 100, and may be specifically located in the center of the display region DA. In an embodiment where the display apparatus includes the first scan driver SD1 and the second scan driver SD2 as described above, the dummy scan driver DSD may be located anywhere between the first scan driver SD1 and the second scan driver SD2. In some embodiments, the dummy scan driver DSD may fill most of the space between the first scan driver SD1 and the second scan driver SD2 in the scan driver layer SDL. The dummy scan driver DSD may have a same (or a very similar) structure as the first scan driver SD1 or the second scan driver SD2.

In the display apparatus according to an embodiment, when viewed in a direction (z-axis direction) perpendicular to the substrate 100, the first scan driver SD1 and/or the second scan driver SD2 is located in the display region DA, and thus, the area of the peripheral region PA of the display apparatus may be minimized.

In such an embodiment, when considering a first portion of the display region DA overlapping the first scan driver SD1 or the second scan driver SD2, and a second portion of the display region DA not overlapping the first scan driver SD1 or the second scan driver SD2, if there is a difference between an environment of a display element located in the first portion and an environment of a display element located in the second portion, it may not be possible to display a high-quality image. Even when same data is applied to the display element located in the first portion and the display element located in the second portion, light of different luminance may be emitted from the display elements due to the difference in the peripheral environments. Accordingly, in the display apparatus according to an embodiment, the dummy scan driver DSD that has the same (or a very similar) structure as the first scan driver SD1 or the second scan driver SD2 overlaps the second portion, and thus, a high-quality image may be displayed throughout the display region DA.

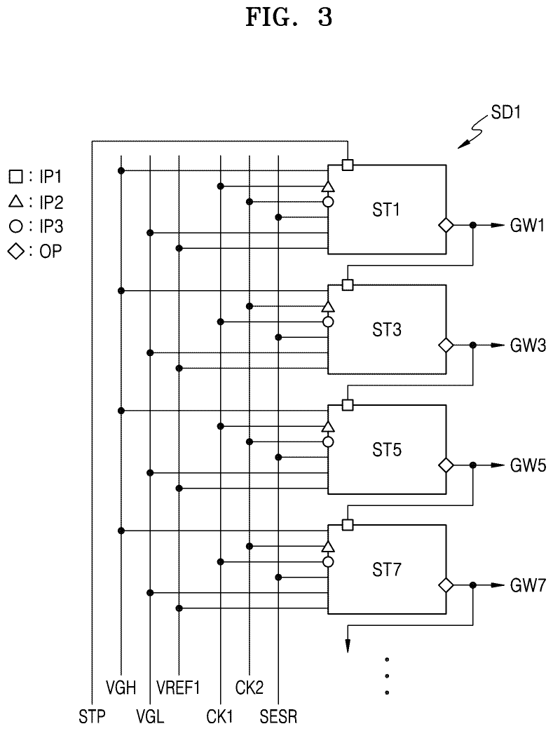

FIG. 3 is a block diagram describing the first scan driver SD1 included in the display apparatus of FIG. 1. As described above, when n is an odd number, the first scan driver SD1 included in the display apparatus according to an embodiment may supply, to the pixels PX located in odd-numbered rows, the scan signals GW[1], GW[3], . . . , and GW[n], the initialization signals GI[1], GI[3], . . . , and GI[n], the compensation control signals GC[1], GC[3], . . . , and GC[n], the light-emission control signals EM[1], EM[3], . . . , and EM[n], or the bias control signals GB[1], GB[3], . . . , and GB[n]. For convenience, FIG. 3 shows a case where the first scan driver SD1 is a scan driver that supplies the scan signals GW[1], GW[3], . . . , and GW[n] to the pixels PX located in odd-numbered rows. For reference, when only the period and timing of clock signals are set differently, a scan driver that supplies the initialization signals GI[1], GI[3], . . . , and GI[n], the compensation control signals GC[1], GC[3], . . . , and GC[n], the light-emission control signals EM[1], EM[3], . . . , and EM[n], or the bias control signals GB[1], GB[3], . . . , and GB[n] may also have the same configuration as the scan driver as shown in FIG. 3.

In an embodiment, as shown in FIG. 3, the first scan driver SD1 may include a plurality of stages ST1, ST3, ST5, ST7, . . . .

Each of the stages ST1, ST3, ST5, and ST7 may include a first input terminal IP1, a second input terminal IP2, a third input terminal IP3, common input terminals, and an output terminal OP. Each of the stages ST1, ST3, ST5, and ST7 may receive a voltage of a high level VGH, a voltage of a low level VGL, a first reference voltage VREF1, and an initialization signal SESR via the common input terminals.

The first input terminal IP1 of the first stage ST1 may receive a scan start signal STP. The first input terminals IP1 of the stages ST3, ST5, ST7, . . . after the first stage ST1 may be connected to the output terminal OP of the previous stage. In other words, the first input terminals IP1 of the stages ST3, ST5, ST7, . . . after the first stage ST1 may receive, as a carry signal, a scan signal output from the previous stage.

The second input terminal IP2 and the third input terminal IP3 of each of the stages ST1, ST3, ST5, and ST7 may receive first and second clock signals CK1 and CK2 which may be different from each other. In an embodiment, for example, the second input terminals IP2 of the stages ST1, ST3, ST5, and ST7 may alternately receive the first clock signal CK1 and the second clock signal CK2. In an embodiment, for example, the second input terminals IP2 of the stages ST1 and ST5 may receive the first clock signal CK1. At this time, the second input terminals IP2 of the stages ST3 and ST7 may receive the second clock signal CK2.

In an embodiment, the third input terminals IP3 of the stages ST1, ST3, ST5, and ST7 may alternately receive the second clock signal CK2 and the first clock signal CK1. In an embodiment, for example, when the third input terminals IP3 of the stages ST1 and ST5 receive the second clock signal CK2, the third input terminals IP3 of the stages ST3 and ST7 may receive the first clock signal CK1.

Each of the stages ST1, ST3, ST5, and ST7 may include a thin-film transistor and/or a capacitor. Each of the stages ST1, ST3, ST5, and ST7 may be implemented by using complementary metal-oxide semiconductor (CMOS). In an embodiment, for example, each of the stages ST1, ST3, ST5, and ST7 may include an initialization portion, a node setting portion, an output portion, and a charge pump. Description of the specific configuration of each of the stages ST1, ST3, ST5, and ST7 is omitted for convenience.

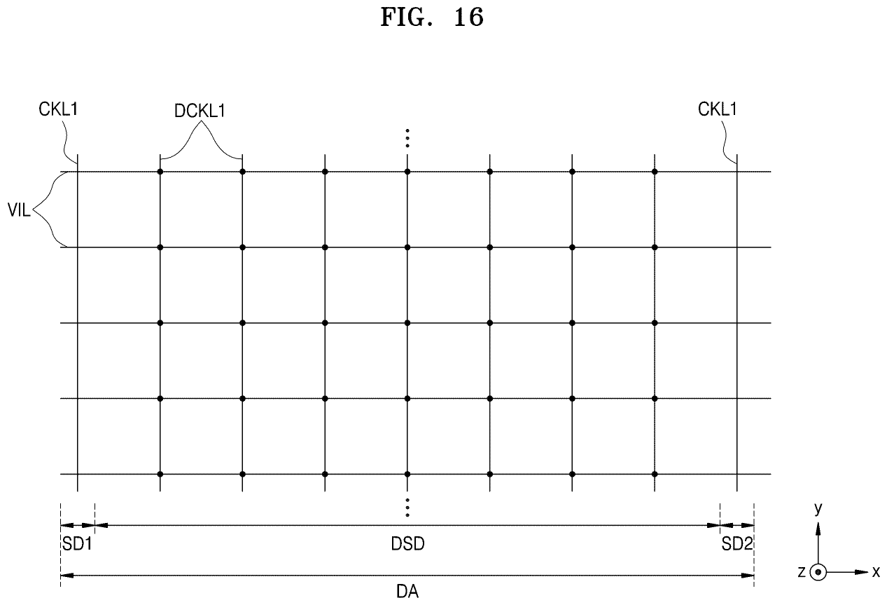

In addition, a first clock line CKL1 (see FIG. 16) or a second clock line may extend along the stages ST1, ST3, ST5, and ST7 to supply the first clock signal CK1 and/or the second clock signal CK2 to the stages ST1, ST3, ST5, and ST7. In other words, the first clock line CKL1 and/or the second clock line, which extend(s) in the first direction (y-axis direction) that is a direction in which the first scan driver SD1 extends, may be present in the first scan driver SD1.

In such an embodiment, the first scan driver SD1 may include stages including a thin-film transistor and a capacitor, and the second scan driver SD2 may have a same (or a very similar) configuration as the first scan driver SD1. The dummy scan driver DSD may also have a same (or a very similar) configuration as the first scan driver SD1. Accordingly, the dummy scan driver DSD may also include a dummy clock line extending in the first direction (y-axis direction).

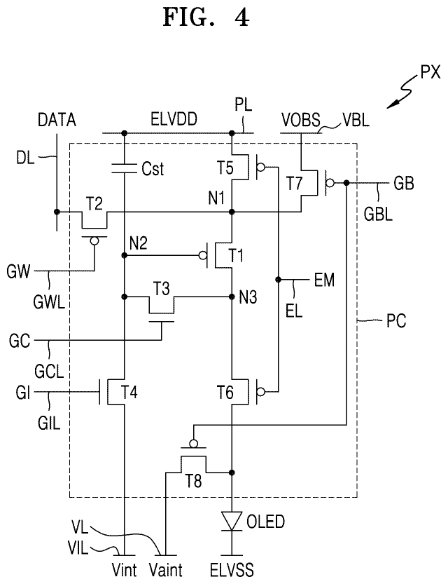

FIG. 4 is an equivalent circuit diagram of one pixel PX included in the display apparatus of FIG. 1. As shown in FIG. 4, one pixel PX may include a pixel circuit PC and an organic light-emitting diode OLED which is a display element electrically connected to the pixel circuit PC.

In an embodiment, as shown in FIG. 4, the pixel circuit PC may include a plurality of thin-film transistors T1 to T8 and a storage capacitor Cst. The plurality of thin-film transistors T1 to T8 and the storage capacitor Cst may be connected to signal lines GWL, GCL, GIL, GBL, EL, and DL, a first initialization voltage line VIL, a second initialization voltage line VL, a driving voltage line PL, and a bias voltage line VBL. At least one of these lines, for example, the driving voltage line PL, may be shared by neighboring pixels PX.

The plurality of thin-film transistors T1 to T8 may include a driving transistor T1, a switching transistor T2, a compensation transistor T3, a first initialization transistor T4, an operation control transistor T5, a light-emission control transistor T6, a bias transistor T7, and a second initialization transistor T8.

The organic light-emitting diode OLED may include a pixel electrode and a common electrode, and the pixel electrode of the organic light-emitting diode OLED may be connected to the driving transistor T1 via the light-emission control transistor T6 and receive a driving current, and the common electrode may receive the electrode voltage ELVSS which is a common voltage. The organic light-emitting diode OLED may generate light of luminance corresponding to the driving current.

Some of the plurality of thin-film transistors T1 to T8 may each be an n-channel metal-oxide-semiconductor field-effect transistor (MOSFET) (NMOS), and the others may each be a p-channel MOSFET (PMOS). In an embodiment, for example, among the plurality of thin-film transistors T1 to T8, the compensation transistor T3 and the first initialization transistor T4 may each be an NMOS, and the others may each be a PMOS. Alternatively, among the plurality of thin-film transistors T1 to T8, the compensation transistor T3, the first initialization transistor T4, and the second initialization transistor T8 may each be an NMOS, and the others may be a PMOS. Alternatively, the plurality of thin-film transistors T1 to T8 may each be an NMOS or a PMOS. The plurality of thin-film transistors T1 to T8 may include amorphous silicon or polysilicon. If desired, a thin-film transistor which is an NMOS may include an oxide semiconductor. Hereinafter, for convenience, an embodiment where the compensation transistor T3 and the first initialization transistor T4 are each an NMOS including an oxide semiconductor and the others are each a PMOS will be mainly described with reference to FIG. 4.

The signal lines may include a first scan line GWL that transmits a first scan signal GW, a second scan line GCL configured to transmit a second scan signal GC, a third scan line GIL that transmits an initialization scan signal GI to the first initialization transistor T4, a fourth scan line GBL that transmits a bias scan signal GB to the second initialization transistor T8, a light-emission control line EL configured to transmit a light-emission control signal EM to the operation control transistor T5 and the light-emission control transistor T6, and a data line DL crossing the first scan line GWL and that transmits a data signal DATA.

The driving voltage line PL may transmit the power voltage ELVDD, which is a driving voltage, to the driving transistor T1, the first initialization voltage line VIL may transmit a first initialization voltage Vint that initializes the driving transistor T1, and the second initialization voltage line VL may be configured to transmit a second initialization voltage Vaint that initializes the pixel electrode of the organic light-emitting diode OLED.

A driving gate electrode of the driving transistor T1 may be connected to the storage capacitor Cst via a second node N2, one of a source region and a drain region of the driving transistor T1 may be connected to the driving voltage line PL via the operation control transistor T5 via a first node N1, and the other of the source region and the drain region of the driving transistor T1 may be electrically connected to the pixel electrode of the organic light-emitting diode OLED via the light-emission control transistor T6 via a third node N3. The driving transistor T1 may receive the data signal DATA based on a switching operation of the switching transistor T2 and supply a driving current to the organic light-emitting diode OLED. In other words, the driving transistor T1 may control the amount of current flowing from the first node N1, which is electrically connected to the driving voltage line PL, to the organic light-emitting diode OLED based on a voltage applied to the second node N2, which varies depending on the data signal DATA.

A switching gate electrode of the switching transistor T2 may be connected to the first scan line GWL that transmits the first scan signal GW, one of a source region and a drain region of the switching transistor T2 may be connected to the data line DL, and the other of the source region and the drain region of the switching transistor T2 may be connected to the driving transistor T1 via the first node N1 and simultaneously connected to the driving voltage line PL via the operation control transistor T5. The switching transistor T2 may transmit, to the first node N1, the data signal DATA from the data line DL based on a voltage applied to the first scan line GWL. In other words, the switching transistor T2 may be turned on in response to the first scan signal GW, which is received via the first scan line GWL, to perform a switching operation to transmit the data signal DATA, which is transmitted to the data line DL, to the driving transistor T1 via the first node N1.

A compensation gate electrode of the compensation transistor T3 is connected to the second scan line GCL. One of a source region and a drain region of the compensation transistor T3 may be connected to the pixel electrode of the organic light-emitting diode OLED via the light-emission control transistor T6 via the third node N3. The other of the source region and the drain region of the compensation transistor T3 may be connected to a first capacitor electrode of the storage capacitor Cst and the driving gate electrode of the driving transistor T1 via the second node N2. The compensation transistor T3 may be turned on in response to the second scan signal GC, which is received via the second scan line GCL, to diode-connect the driving transistor T1.

A first initialization gate electrode of the first initialization transistor T4 may be connected to the third scan line GIL. One of a source region and a drain region of the first initialization transistor T4 may be connected to the first initialization voltage line VIL. The other of the source region and the drain region of the first initialization transistor T4 may be connected to the first capacitor electrode of the storage capacitor Cst and the driving gate electrode of the driving transistor T1 via the second node N2. The first initialization transistor T4 may apply, to the second node N2, the first initialization voltage Vint from the first initialization voltage line VIL based on a voltage applied to the third scan line GIL. In other words, the first initialization transistor T4 may be turned on in response to the initialization scan signal GI, which is received via the third scan line GIL, to transmit the first initialization voltage Vint to the driving gate electrode of the driving transistor T1 and perform an initialization operation to initialize a voltage of the driving gate electrode of the driving transistor T1.

An operation control gate electrode of the operation control transistor T5 may be connected to the light-emission control line EL, one of a source region and a drain region of the operation control transistor T5 may be connected to the driving voltage line PL, and the other of the source region and the drain region of the operation control transistor T5 may be connected to the driving transistor T1 and the switching transistor T2 via the first node N1.

A light-emission control gate electrode of the light-emission control transistor T6 may be connected to the light-emission control line EL, one of a source region and a drain region of the light-emission control transistor T6 may be connected to the driving transistor T1 and the compensation transistor T3 via the third node N3, and the other of the source region and the drain region of the light-emission control transistor T6 may be electrically connected to the pixel electrode of the organic light-emitting diode OLED.

The operation control transistor T5 and the light-emission control transistor T6 may be simultaneously turned on according to the light-emission control signal EM, which is received via the light-emission control line EL, to transfer an electrical signal from the power voltage ELVDD to the organic light-emitting diode OLED, such that a driving current may flow through the organic light-emitting diode OLED.

The bias transistor T7 may be connected between the first node N1 and the bias voltage line VBL. The bias transistor T7 may be turned on in response to the bias scan signal GB, which is received via the fourth scan line GBL, to apply a bias voltage VOBS to the first node N1 such that a voltage at the first node N1 suitable for a subsequent operation of the driving transistor T1 is pre-set. From this perspective, the fourth scan line GBL may be referred to as a bias gate line.

A second initialization gate electrode of the second initialization transistor T8 may be connected to the fourth scan line GBL, one of a source region and a drain region of the second initialization transistor T8 may be connected to the pixel electrode of the organic light-emitting diode OLED, and the other of the source region and the drain region of the second initialization transistor T8 may be connected to the second initialization voltage line VL to receive the second initialization voltage Vaint. The second initialization transistor T8 is turned on in response to the bias scan signal GB, which is received via the fourth scan line GBL, to initialize the pixel electrode of the organic light-emitting diode OLED.

The storage capacitor Cst may include the first capacitor electrode and a second capacitor electrode. The first capacitor electrode of the storage capacitor Cst is connected to the driving gate electrode of the driving transistor T1 via the second node N2, and the second capacitor electrode of the storage capacitor Cst is connected to the driving voltage line PL. The storage capacitor Cst may store a charge corresponding to a difference between a voltage of the driving gate electrode of the driving transistor T1 and the power voltage ELVDD.

In the display apparatus according to an embodiment, a specific operation of each pixel PX is as follows.

During an initialization period, when the initialization scan signal GI (having a turn-on level) is supplied via the third scan line GIL, the first initialization transistor T4 is turned on by the initialization scan signal GI, and the driving transistor T1 is initialized by the first initialization voltage Vint supplied from the first initialization voltage line VIL. In addition, when the bias scan signal GB (having a turn-on level) is supplied via the fourth scan line GBL, the second initialization transistor T8 is turned on in accordance with the bias scan signal GB, and the pixel electrode of the organic light-emitting diode OLED is initialized by the second initialization voltage Vaint supplied from the second initialization voltage line VL. In addition, the bias transistor T7 is also turned on by the bias scan signal GB to apply the bias voltage VOBS to the first node N1, such that a voltage at the first node N1 suitable for a subsequent operation of the driving transistor T1 is pre-set.

During a data programming period, when the first scan signal GW and the second scan signal GC (each having a turn-on level) are supplied via the first scan line GWL and the second scan line GCL, the switching transistor T2 and the compensation transistor T3 are turned on by the first scan signal GW and the second scan signal GC. At this time, the driving transistor T1 is diode-connected by the turned-on compensation transistor T3 and forward biased. Then, a compensation voltage (DATA+Vₜₕ, where Vₜₕ has a negative (−) value), which is obtained by reducing the data signal DATA supplied from the data line DL by a threshold voltage (Vₜₕ) of the driving transistor T1, is applied to a driving gate electrode G1 of the driving transistor T1. The power voltage ELVDD and the compensation voltage (DATA+Vₜₕ) are applied to respective ends of the storage capacitor Cst, and a charge corresponding to a difference between voltages at both ends is stored in the storage capacitor Cst.

During a light-emission period, the operation control transistor T5 and the light-emission control transistor T6 are turned on by the light-emission control signal EM (having a turn-on level) supplied from the light-emission control line EL. A driving current is generated according to a difference between a voltage of the driving gate electrode G1 of the driving transistor T1 and the power voltage ELVDD, and the driving current is supplied to the organic light-emitting diode OLED via the light-emission control transistor T6.

As described above, some of the plurality of thin-film transistors T1 to T8 may include an oxide semiconductor. In an embodiment, for example, the compensation transistor T3 and the first initialization transistor T4 may include an oxide semiconductor.

Polysilicon has high reliability and thus may be controlled to allow the flow of a precisely intended current. Therefore, the driving transistor T1, which directly affects the brightness of the display apparatus, includes a semiconductor layer including polysilicon having high reliability, thereby enabling a high-resolution display apparatus to be implemented. Oxide semiconductors have high carrier mobility and low leakage current, and thus, there is no significant voltage drop even when a driving time is long. In other words, in the case of oxide semiconductors, there is no significant color change in an image due to voltage drop even during low-frequency driving, and thus, low-frequency driving is possible. Therefore, the compensation transistor T3 and the first initialization transistor T4 include an oxide semiconductor to prevent occurrence of leakage current and implement a display apparatus with reduced power consumption.

In an embodiment, such oxide semiconductors are sensitive to light, and thus, changes in current amount may occur due to light from the outside. Therefore, a metal layer may be disposed under an oxide semiconductor to absorb or reflect light from the outside. Accordingly, as shown in FIG. 4, the compensation transistor T3 and the first initialization transistor T4, which each include an oxide semiconductor, may each have gate electrodes respectively disposed on an upper portion and lower portion of an oxide semiconductor layer. In other words, when viewed in a direction (z-axis direction) perpendicular to an upper surface of the substrate 100, the metal layer disposed under the oxide semiconductor may overlap the oxide semiconductor.

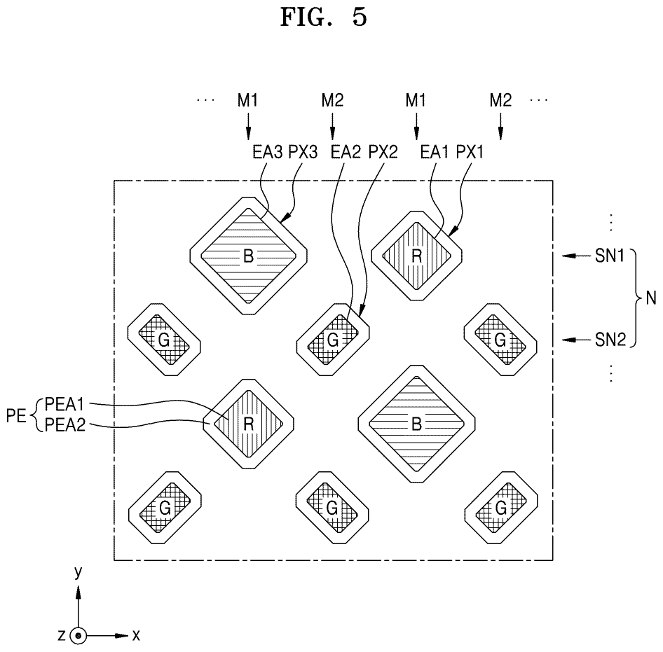

FIG. 5 is a plan view schematically showing emission regions of a plurality of pixels included in the display apparatus of FIG. 1.

A plurality of pixels arranged in the display region DA may include a first pixel PX1, a second pixel PX2, and a third pixel PX3. The first pixel PX1, the second pixel PX2, and the third pixel PX3 may be repeatedly arranged in the x-axis direction and the y-axis direction according to a certain pattern. Each of the first pixel PX1, the second pixel PX2, and the third pixel PX3 may include a pixel circuit and the organic light-emitting diode OLED electrically connected to the pixel circuit. The organic light-emitting diode OLED of each pixel may be in a layer disposed over the pixel circuit. The organic light-emitting diode OLED may be disposed directly over the pixel circuit to overlap the pixel circuit, or may be offset from the pixel circuit and arranged to partially overlap the pixel circuit of another pixel arranged in an adjacent row and/or column.

FIG. 5 shows a pixel electrode PE and emission region of each of the first pixel PX1, the second pixel PX2, and the third pixel PX3. The emission region is a region where an emission layer of the organic light-emitting diode OLED is arranged. The emission region may be defined by a pixel-defining film having an opening corresponding to a central portion of the pixel electrode PE. Each of the pixel electrodes PE may include a first region PEA1 corresponding to the emission region and a second region PEA2 surrounding the first region PEA1. The first region PEA1 may correspond to the opening in the pixel-defining film, and the second region PEA2 may be a portion covered by the pixel-defining film.

In a first column M1, a first emission region EA1 of the first pixel PX1 and a third emission region EA3 of the third pixel PX3 may be alternately arranged in the y-axis direction. In a second column M2, a second emission region EA2 of the second pixel PX2 may be repeatedly arranged in the y-axis direction. The first column M1 and the second column M2 may be alternately arranged in the x-axis direction, and the arrangements of the first emission region EA1 of the first pixel PX1 and the third emission region EA3 of the third pixel PX3, in adjacent first columns M1 may be opposite to each other.

In a first sub-row SN1 of each row N, the first emission region EA1 of the first pixel PX1 and the third emission region EA3 of the third pixel PX3 may be alternately arranged in the x-axis direction, and in a second sub-row SN2, the second emission region EA2 of the second pixel PX2 may be repeatedly arranged in the x-axis direction. In other words, in each row N, the first emission region EA1 of the first pixel PX1, the second emission region EA2 of the second pixel PX2, the third emission region EA3 of the third pixel PX3, and the second emission region EA2 of the second pixel PX2 may be repeatedly arranged in a zigzag shape.

The first emission region EA1 of the first pixel PX1, the second emission region EA2 of the second pixel PX2, and the third emission region EA3 of the third pixel PX3 may have different areas. In an embodiment, for example, the third emission region EA3 of the third pixel PX3 may have a larger area than the first emission region EA1 of the first pixel PX1. In addition, the third emission region EA3 of the third pixel PX3 may have a larger area than the second emission region EA2 of the second pixel PX2. The first emission region EA1 of the first pixel PX1 may have a larger area than the second emission region EA2 of the second pixel PX2. In another embodiment, the third emission region EA3 of the third pixel PX3 may have a same area as the first emission region EA1 of the first pixel PX1. However, the disclosure is not limited thereto. In an embodiment, for example, the first emission region EA1 of the first pixel PX1 may be larger than the second emission region EA2 of the second pixel PX2 and the third emission region EA3 of the third pixel PX3, and various modifications may be made.

The first emission region EA1, the second emission region EA2, and the third emission region EA3 may have a polygonal shape such as a quadrangle or an octagon, or may have a circular shape or an elliptical shape. In an embodiment where the first emission region EA1, the second emission region EA2, and the third emission region EA3 have the polygonal shape, the corners (vertices) thereof may be rounded.

The first pixel PX1 may be a red pixel R that emits red light, the second pixel PX2 may be a green pixel G that emits green light, and the third pixel PX3 may be a blue pixel B that emits blue light.

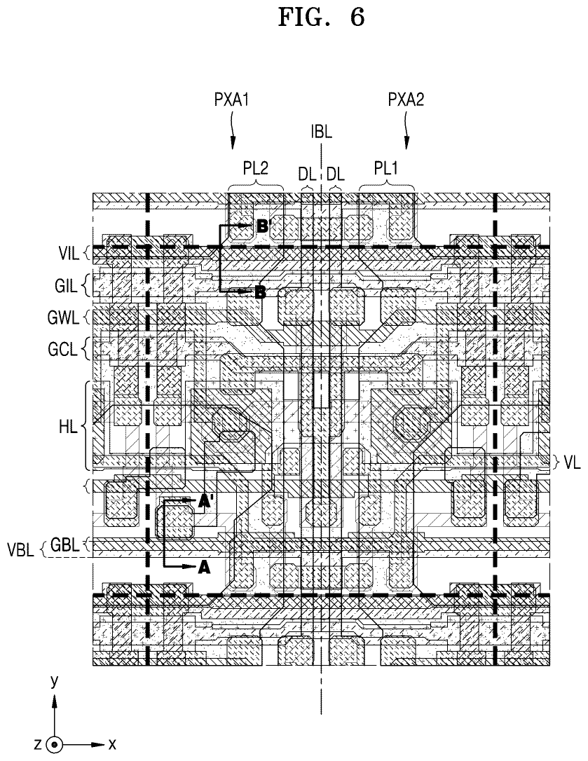

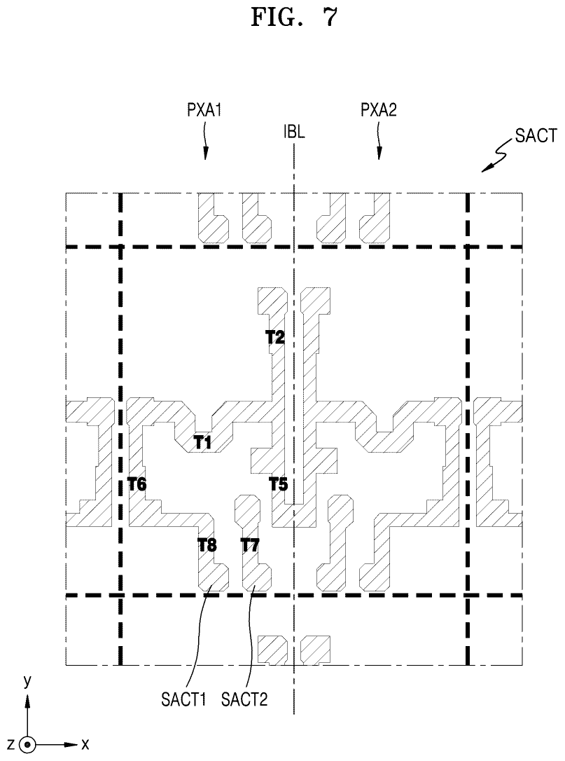

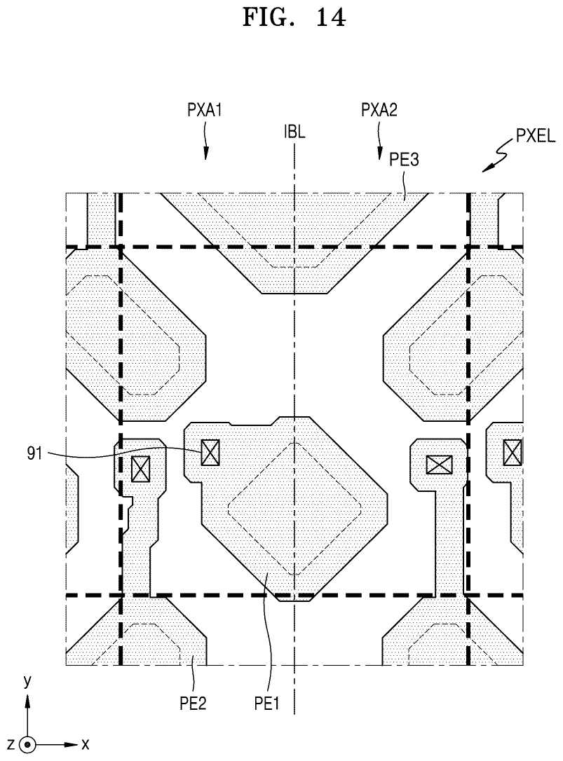

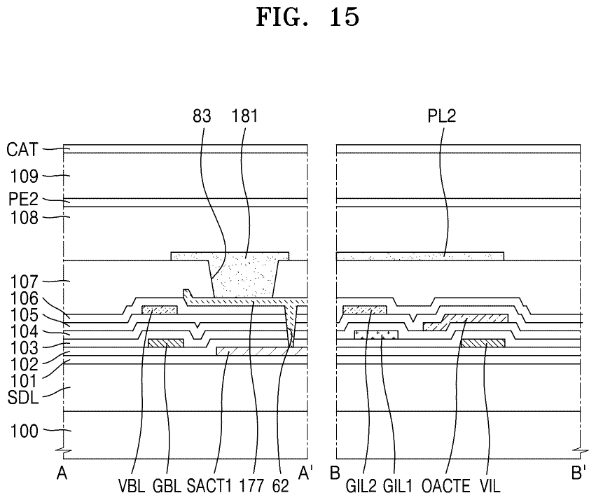

FIG. 6 is a plan view schematically showing positions of transistors, capacitors, etc. in pixels included in the display apparatus of FIG. 1, FIGS. 7 to 13 are plan views schematically showing components, such as transistors and capacitors, of the display apparatus shown in FIG. 6, for each layer, FIG. 14 is a plan view schematically showing a pixel electrode layer of the display apparatus shown in FIG. 6, and FIG. 15 is a cross-sectional view schematically showing cross-sections taken along lines A-A′ and B-B′ of FIG. 6.

As shown in these drawings, an embodiment of the display apparatus may include a first pixel region PXA1 and a second pixel region PXA2, which are adjacent to each other. The pixel circuit of the first pixel PX1 may be arranged in the first pixel region PXA1, and the pixel circuit of the second pixel PX2 may be arranged in the second pixel region PXA2. The first pixel region PXA1 and the second pixel region PXA2 may be approximately symmetrical to each other with respect to an imaginary boundary line IBL, as shown in FIG. 6, etc. In another embodiment, the first pixel region PXA1 and the second pixel region PXA2 may have a same structure rather than a symmetrical structure. Hereinafter, for convenience of description, some conductive patterns may be described based on the pixel circuit arranged in the first pixel region PXA1, but these conductive patterns may also be arranged in the second pixel region PXA2 in a symmetric manner or an identical manner.

For reference, the structures as shown in FIGS. 6 to 13 may be repeated in the first direction (y-axis direction) and may also be repeated in the second direction (x-axis direction).

A buffer layer 101 (see FIG. 15) including silicon oxide, silicon nitride, or silicon oxynitride may be disposed over the substrate 100. The buffer layer 101 may prevent diffusion of metal atoms or impurities from the substrate 100 into a first semiconductor layer SACT disposed on the buffer layer 101. In addition, the buffer layer 101 may allow the first semiconductor layer SACT to be uniformly crystallized by controlling a heat provision rate during a crystallization process for forming the first semiconductor layer SACT.

The first semiconductor layer SACT, as shown in FIGS. 7 and 15, may be disposed on the buffer layer 101. The first semiconductor layer SACT may include a silicon semiconductor. In an embodiment, the first semiconductor layer SACT may include amorphous silicon or polysilicon. In an embodiment, for example, the first semiconductor layer SACT may include polysilicon crystallized at low temperature. If desired, ions may be implanted into at least a portion of the first semiconductor layer SACT.

The first semiconductor layer SACT may include a first sub-semiconductor layer SACT1 and a second sub-semiconductor layer SACT2 separated (or disconnected) from the first sub-semiconductor layer SACT1. The first sub-semiconductor layer SACT1 of the first pixel region PXA1 and the first sub-semiconductor layer SACT1 of the second pixel region PXA2 may be integrally formed as a single unitary indivisible body. The second sub-semiconductor layer SACT2 may be electrically connected to the first sub-semiconductor layer SACT1 by a connection electrode 176 included in a first connection electrode layer CEL1, as described below.

The first sub-semiconductor layer SACT1 may have various curved shapes. The driving transistor T1, the switching transistor T2, the operation control transistor T5, the light-emission control transistor T6, and the second initialization transistor T8 may be located along the first sub-semiconductor layer SACT1. In other words, the first sub-semiconductor layer SACT1 may include (or define) a channel region of each of the driving transistor T1, the switching transistor T2, the operation control transistor T5, the light-emission control transistor T6, and the second initialization transistor T8, and a source region and a drain region on either side of the channel region. The second sub-semiconductor layer SACT2 may include (or define) a channel region, source region, and drain region of the bias transistor T7. In FIG. 7, the positions of the channel regions of the transistors T1, T2, and T5 to T8 are indicated by reference symbols of the transistors T1, T2, and T5 to T8. The source region or the drain region is arranged on one side and an opposing side of the channel region.

A first gate insulating layer 102 (see FIG. 15) may cover the first semiconductor layer SACT and may be disposed over the substrate 100. The first gate insulating layer 102 may include an insulating material. In an embodiment, for example, the first gate insulating layer 102 may include silicon oxide, silicon nitride, silicon oxynitride, or aluminum oxide.

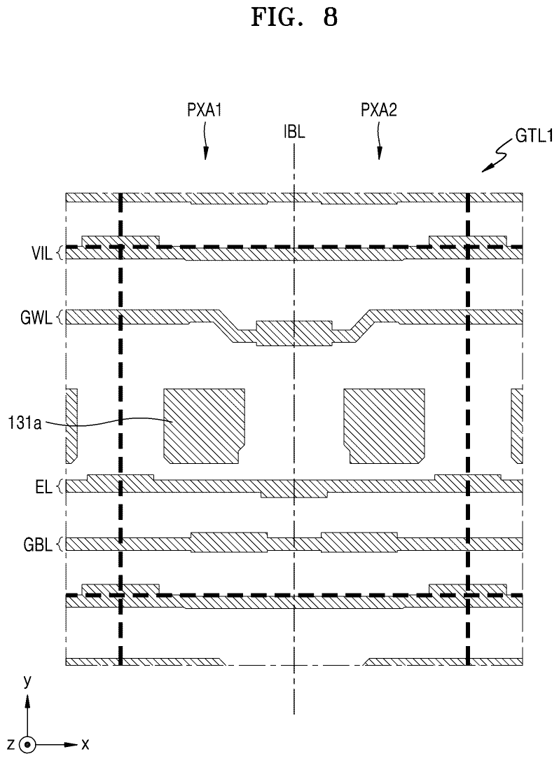

A first gate layer GTL1, as shown in FIGS. 8 and 15, may be disposed on the first gate insulating layer 102. The first gate layer GTL1 may include (or define) the first scan line GWL that transmits the first scan signal GW, the fourth scan line GBL that transmits the bias scan signal GB to the second initialization transistor T8, the light-emission control line EL that transmits the light-emission control signal EM to the operation control transistor T5 and the light-emission control transistor T6, the first initialization voltage line VIL that transmits the first initialization voltage Vint to initialize the driving transistor T1, and a driving gate electrode 131a of the driving transistor T1, which has an isolated shape. The driving gate electrode 131a may also serve as a lower electrode, which is the first capacitor electrode of the storage capacitor Cst.

The first scan line GWL, the fourth scan line GBL, the light-emission control line EL, and the first initialization voltage line VIL may have a shape extending approximately in the second direction (x-axis direction). Portions overlapping the first semiconductor layer SACT of the first scan line GWL, the fourth scan line GBL, and the light-emission control line EL may serve as gate electrodes of transistors. In other words, the portion overlapping the first semiconductor layer SACT of the first scan line GWL may be the switching gate electrode of the switching transistor T2, the portion overlapping the first semiconductor layer SACT of the fourth scan line GBL may be a bias gate electrode of the bias transistor T7, and the portions overlapping the first semiconductor layer SACT of the light-emission control line EL may be the operation control gate electrode of the operation control transistor T5 and the light-emission control gate electrode of the light-emission control transistor T6.

The first gate layer GTL1 may include a metal, an alloy, a conductive metal oxide, or a transparent conductive material. In an embodiment, for example, the first gate layer GTL1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The first gate layer GTL1 may have a multilayer structure, and for example, the first gate layer GTL1 may have a two-layer structure of Mo/Al or a three-layer structure of Mo/Al/Mo.

A second gate insulating layer 103 (see FIG. 15) may cover the first gate layer GTL1 and may be disposed on the first gate insulating layer 102. The second gate insulating layer 103 may include the same/similar insulating material as the first gate insulating layer 102.

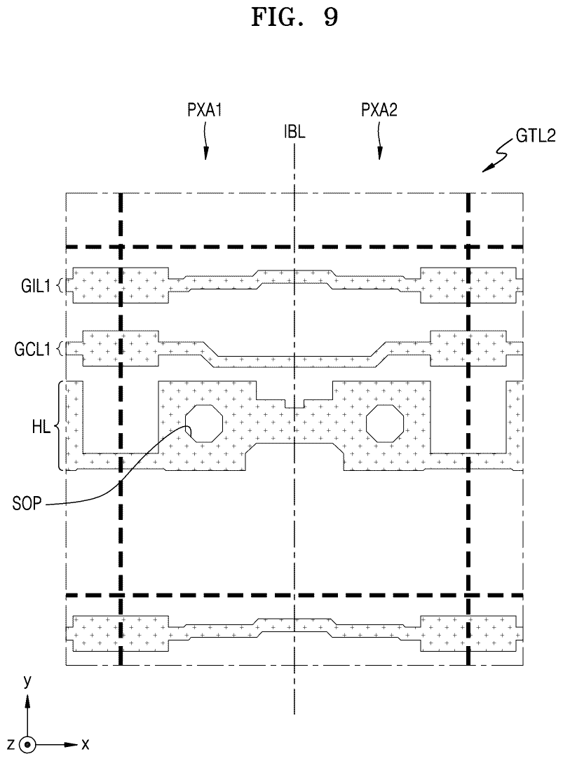

A second gate layer GTL2, as shown in FIGS. 9 and 15, may be disposed on the second gate insulating layer 103. The second gate layer GTL2 may include (or define) an electrode voltage line HL, a lower gate line GCL1 of the second scan line GCL, and a lower gate line GIL1 of the third scan line GIL. The electrode voltage line HL, the lower gate line GCL1 of the second scan line GCL, and the lower gate line GIL1 of the third scan line GIL may extend in the second direction (x-axis direction).

A portion of the electrode voltage line HL is an upper electrode, which is a second storage electrode of the storage capacitor Cst, and may overlap the driving gate electrode 131a, which is the lower electrode of the storage capacitor Cst. Because portions of the electrode voltage line HL are upper electrodes of the storage capacitors Cst, the upper electrodes of the storage capacitors Cst of pixel circuits in a same row may be integrally formed as a single unitary indivisible body. The power voltage ELVDD may be applied to the upper electrode of the storage capacitor Cst. An opening SOP may be defined in the upper electrode of the storage capacitor Cst, and at least a portion of the driving gate electrode 131a may overlap the opening SOP.

A portion of the lower gate line GCL1 of the second scan line GCL, overlapping a second semiconductor layer OACT, which may be an oxide semiconductor layer and will be described later, may be a compensation lower gate electrode of the compensation transistor T3, and a portion of the lower gate line GIL1 of the third scan line GIL, overlapping the second semiconductor layer OACT, may be a first initialization lower gate electrode of the first initialization transistor T4.

The second gate layer GTL2 may include a metal, an alloy, a conductive metal oxide, or a transparent conductive material. In an embodiment, for example, the second gate layer GTL2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The second gate layer GTL2 may have a multilayer structure, and for example, the second gate layer GTL2 may have a two-layer structure of Mo/Al or a three-layer structure of Mo/Al/Mo.

A first interlayer insulating layer 104 (see FIG. 15) may cover the second gate layer GTL2 and may be disposed on the second gate insulating layer 103. The first interlayer insulating layer 104 may include an insulating material. In an embodiment, for example, the first interlayer insulating layer 104 may include silicon oxide, silicon nitride, silicon oxynitride, or aluminum oxide.

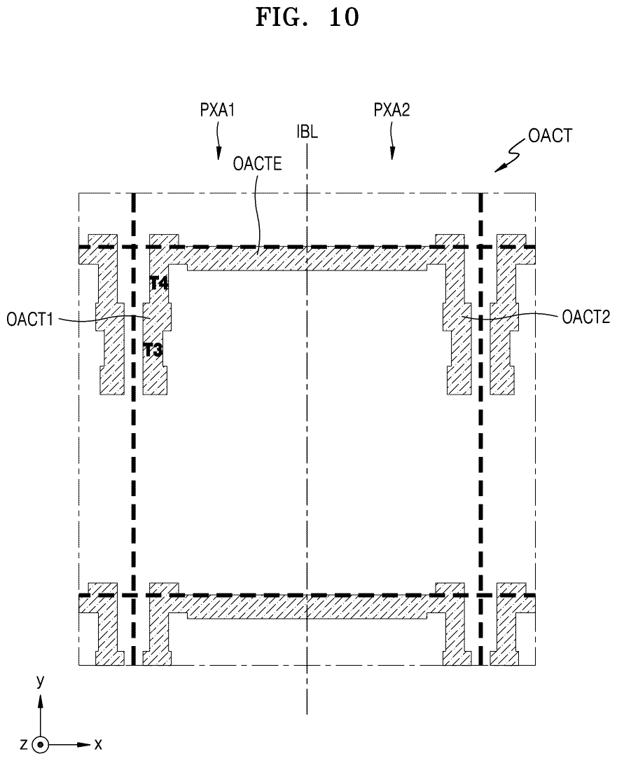

The second semiconductor layer OACT, as shown in FIGS. 10 and 15, may be disposed on the first interlayer insulating layer 104. As described above, the second semiconductor layer OACT may include an oxide semiconductor. The second semiconductor layer OACT may be disposed in (or directly on) a different layer from the first semiconductor layer SACT, and may not overlap the first semiconductor layer SACT when viewed in a direction (z-axis direction) perpendicular to the substrate 100. The second semiconductor layer OACT may constitute the compensation transistor T3 and the first initialization transistor T4. In FIG. 10, the positions of channel regions of the transistors T3 and T4 are indicated by reference symbols of the transistors T3 and T4. A source region or a drain region is arranged on one side and an opposing side of a channel region.

The second semiconductor layer OACT may include a first second semiconductor layer OACT1 arranged in the first pixel region PXA1 and extending in the first direction (y-axis direction), and a semiconductor extension layer OACTE extending from the first second semiconductor layer OACT1 in the second direction (x-axis direction). A second second semiconductor layer OACT2 extending in the first direction (y-axis direction) may be arranged in the second pixel region PXA2, and one end of the semiconductor extension layer OACTE may be connected to the first second semiconductor layer OACT1, and an opposing end thereof may be connected to the second second semiconductor layer OACT2. In other words, the first second semiconductor layer OACT1 arranged in the first pixel region PXA1, the second second semiconductor layer OACT2 arranged in the second pixel region PXA2, and the semiconductor extension layer OACTE may be integrally formed as a single unitary indivisible body.

The second semiconductor layer OACT may be an oxide-containing semiconductor layer, as described above. In an embodiment, for example, the second semiconductor layer OACT may include a Zn oxide-based material, for example, Zn oxide, In—Zn oxide, or Ga—In—Zn oxide. Various modifications may be made, and thus, the second semiconductor layer OACT may include an oxide semiconductor, such as In—Ga—Zn—O (IGZO), In—Sn—Zn—O (ITZO), or In—Ga—Sn—Zn—O (IGTZO), containing a metal, such as indium (In), gallium (Ga), or tin (Sn), in ZnO.

A third gate insulating layer 105 (see FIG. 15) may cover the second semiconductor layer OACT and may be disposed on the first interlayer insulating layer 104. The third gate insulating layer 105 may include an insulating material. The third gate insulating layer 105 may include silicon oxide, silicon nitride, silicon oxynitride, or aluminum oxide.

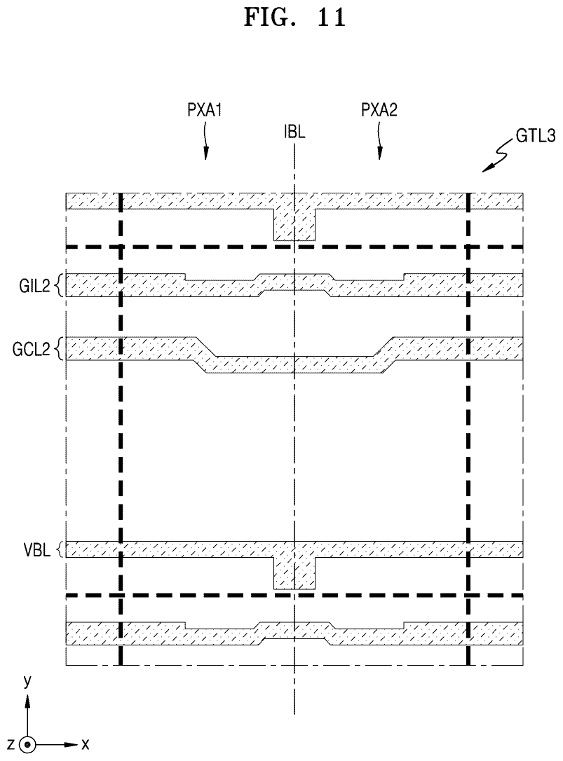

A third gate layer GTL3, as shown in FIGS. 11 and 15, may be disposed on the third gate insulating layer 105. The third gate layer GTL3 may include (or define) an upper gate line GCL2 of the second scan line GCL, an upper gate line GIL2 of the third scan line GIL, and the bias voltage line VBL. The upper gate line GCL2 of the second scan line GCL, the upper gate line GIL2 of the third scan line GIL, and the bias voltage line VBL may extend in the second direction (x-axis direction).

A portion of the upper gate line GCL2 of the second scan line GCL, overlapping the oxide semiconductor layer OACT, may be a compensation upper gate electrode of the compensation transistor T3, and a portion of the upper gate line GIL2 of the third scan line GIL, overlapping the oxide semiconductor layer OACT, may be a first initialization upper gate electrode of the first initialization transistor T4. In other words, the compensation transistor T3 and the first initialization transistor T4 may have a double-gate structure having gate electrodes respectively disposed over and below the second semiconductor layer OACT.

The third gate layer GTL3 may include a metal, an alloy, a conductive metal oxide, or a transparent conductive material. In an embodiment, for example, the third gate layer GTL3 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The third gate layer GTL3 may have a multilayer structure, and for example, the third gate layer GTL3 may have a two-layer structure of Mo/Al or a three-layer structure of Mo/Al/Mo.

A second interlayer insulating layer 106 (see FIG. 15) may cover at least a portion of the third gate layer GTL3 of FIG. 11. The second interlayer insulating layer 106 may include an insulating material. In an embodiment, for example, the second interlayer insulating layer 106 may include silicon oxide, silicon nitride, silicon oxynitride, or aluminum oxide.

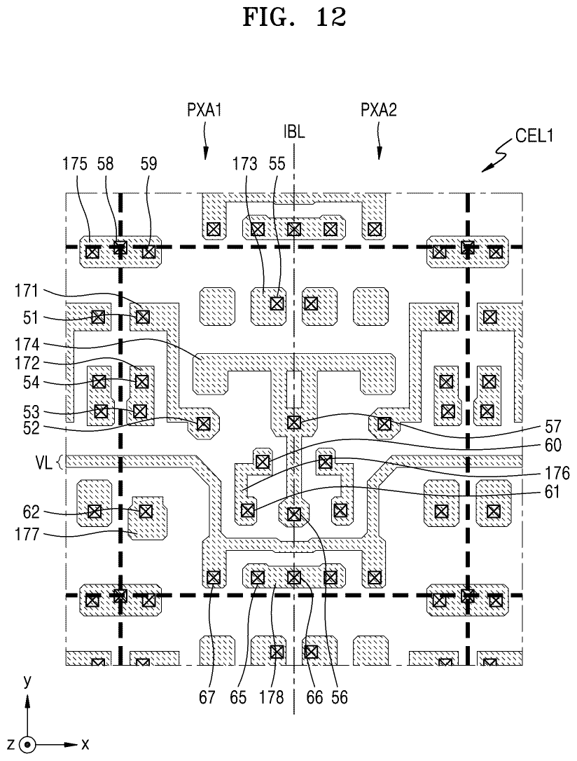

The first connection electrode layer CEL1, as shown in FIGS. 12 and 15, may be disposed on the second interlayer insulating layer 106. The first connection electrode layer CEL1 may include (or define) the second initialization voltage line VL and connection electrodes 171 to 178. The second initialization voltage line VL may have a shape extending approximately in the second direction (x-axis direction). The connection electrodes 171 to 178 may have an isolated shape.

The second initialization voltage line VL may be connected to the first semiconductor layer SACT via a contact hole 67 defined in the insulating layer disposed under the second initialization voltage line VL, in the first pixel region PXA1 in which the pixel circuit of the first pixel PX1 is arranged, and thus may be electrically connected to the drain region of the second initialization transistor T8. The second initialization voltage line VL may be curved and extend in a zigzag shape in the second direction (x-axis direction).

One end of the connection electrode 171 may be in contact with the second semiconductor layer OACT via a contact hole 51 and electrically connected to the second semiconductor layer OACT. In detail, one end of the connection electrode 171 may be electrically connected to the source region of the compensation transistor T3 and the drain region of the first initialization transistor T4 via the contact hole 51 defined in the insulating layers disposed under the connection electrode 171. An opposing end of the connection electrode 171 may be electrically connected to the driving gate electrode 131a of the driving transistor T1, which also serves as the lower electrode of the storage capacitor Cst, via a contact hole 52 defined in the insulating layers disposed under the connection electrode 171. The contact hole 52 may pass through the opening SOP of the upper electrode of the storage capacitor Cst.

The connection electrode 172 may be electrically connected to the drain region of the driving transistor T1 and the source region of the light-emission control transistor T6 via a contact hole 53 defined in the insulating layers disposed under the connection electrode 172. In addition, the connection electrode 172 may be electrically connected to the drain region of the compensation transistor T3 via a contact hole 54 defined in the insulating layers disposed under the connection electrode 172.

The connection electrode 173 may be electrically connected to the source region of the switching transistor T2 via a contact hole 55 defined in the insulating layers disposed under the connection electrode 173.

The connection electrode 174 may be electrically connected to the source region of the operation control transistor T5 via a contact hole 56 defined in the insulating layers disposed under the connection electrode 174. In addition, the connection electrode 174 may be electrically connected to the electrode voltage line HL, which serves as the upper electrode of the storage capacitor Cst, via a contact hole 57 defined in the insulating layers disposed under the connection electrode 174.

The connection electrode 175 may be electrically connected to the first initialization voltage line VIL via a contact hole 58 defined in the insulating layers disposed below the connection electrode 175. In addition, the connection electrode 175 may be electrically connected to the drain region of the first initialization transistor T4 via a contact hole 59 defined in the insulating layers disposed below the connection electrode 175. Accordingly, the first initialization voltage Vint, which is a constant voltage, may be applied to the semiconductor extension layer OACTE of the second semiconductor layer OACT.

The connection electrode 176 may electrically connect the first sub-semiconductor layer SACT1 to the second sub-semiconductor layer SACT2. In detail, the connection electrode 176 may be electrically connected to the source region of the driving transistor T1, the drain region of the operation control transistor T5, and the drain region of the switching transistor T2 via a contact hole 60 defined in the insulating layers disposed under the connection electrode 176. In addition, the connection electrode 176 may be electrically connected to the drain region of the bias transistor T7 via a contact hole 61 defined in the insulating layers disposed under the connection electrode 176.

The connection electrode 177 may be electrically connected to the drain region of the light-emission control transistor T6 via a contact hole 62 defined in the insulating layers disposed under the connection electrode 177.

The connection electrode 178 may be electrically connected to the source region of the bias transistor T7 via a contact hole 65 defined in the insulating layers disposed under the connection electrode 178. In addition, the connection electrode 178 may be electrically connected to the bias voltage line VBL via a contact hole 66 defined in the insulating layer disposed under the connection electrode 178.

The first connection electrode layer CEL1 may include a metal, an alloy, a conductive metal oxide, or a transparent conductive material. In an embodiment, for example, the first connection electrode layer CEL1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The first connection electrode layer CEL1 may have a multilayer structure, and for example, the first connection electrode layer CEL1 may have a two-layer structure of Ti/Al or a three-layer structure of Ti/Al/Ti.

A first planarization insulating layer 107 (see FIG. 15) may cover the first connection electrode layer CEL1 and may be disposed on the second interlayer insulating layer 106. The first planarization insulating layer 107 may include an organic insulating material. In an embodiment, for example, the first planarization insulating layer 107 may include photoresist, benzocyclobutene (BCB), polyimide, hexamethyldisiloxane (HMDSO), polymethylmethacrylate (PMMA), polystyrene, polymer derivatives with phenolic groups, acrylic polymers, imide polymers, aryl ether-based polymers, amide-based polymers, fluorine-based polymers, p-xylene-based polymers, vinyl alcohol-based polymers, or a mixture thereof.

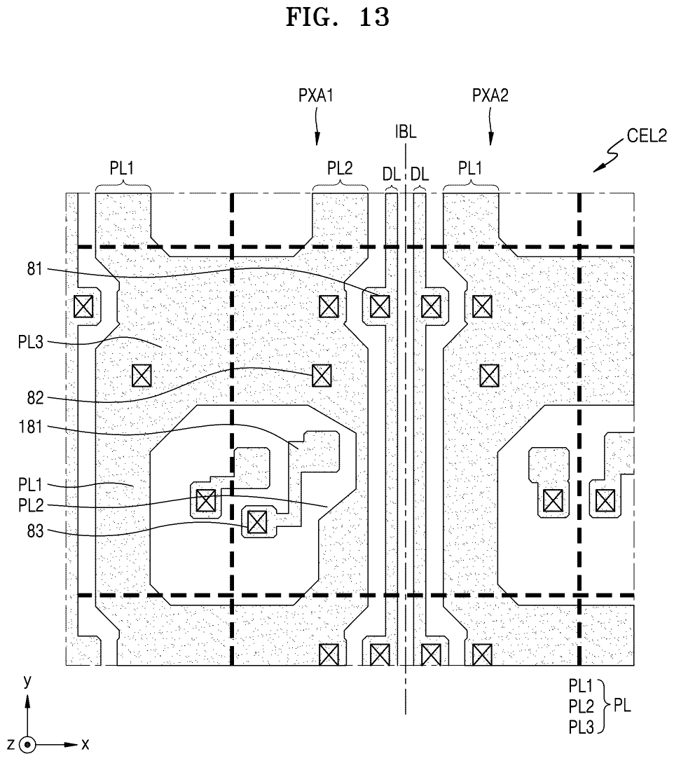

A second connection electrode layer CEL2, as shown in FIGS. 13 and 15, may be disposed on the first planarization insulating layer 107. The second connection electrode layer CEL2 may include (or define) the data line DL, the driving voltage line PL, and a connection electrode 181. The data line DL and the driving voltage line PL may have a shape extending approximately in the first direction (y-axis direction).

The data line DL is electrically connected to the connection electrode 173 included in the first connection electrode layer CEL1 via a contact hole 81 defined in the first planarization insulating layer 107 disposed under the data line DL. As described above, the connection electrode 173 is connected to the source region of the switching transistor T2 via the contact hole 55 defined in the insulating layers disposed under the connection electrode 173, and as a result, the data line DL may be electrically connected to the source region of the switching transistor T2.

The driving voltage line PL extending in the first direction (y-axis direction) may be electrically connected to the connection electrode 174 included in the first connection electrode layer CEL1 via a contact hole 82 defined in the first planarization insulating layer 107 disposed under the driving voltage line PL. As described above, the connection electrode 174 is connected to the electrode voltage line HL, which is included in the second gate layer GTL2 and extends in the second direction (x-axis direction), via the contact hole 57 defined in the insulating layers disposed under the connection electrode 174. Therefore, the driving voltage line PL and the electrode voltage line HL, which are electrically connected to each other, may have an overall mesh structure. Accordingly, in the display region DA, voltage drop (IR drop) of the power voltage ELVDD may be effectively prevented or substantially minimized.

The driving voltage line PL may include a plurality of first driving voltage branches PL1, a plurality of second driving voltage branches PL2, and a plurality of driving voltage bodies PL3. The plurality of driving voltage bodies PL3 may be arranged in the first direction (y-axis direction). The plurality of second driving voltage branches PL2 may be spaced apart from the plurality of first driving voltage branches PL1 in the first direction (x-axis direction).

Each of the plurality of first driving voltage branches PL1 and each of the plurality of second driving voltage branches PL2 may have a shape extending in the first direction (y-axis direction). Each of the plurality of first driving voltage branches PL1 and each of the plurality of second driving voltage branches PL2 may be arranged between the plurality of driving voltage bodies PL3 to connect the plurality of driving voltage bodies PL3. Accordingly, the plurality of first driving voltage branches PL1, the plurality of second driving voltage branches PL2, and the plurality of driving voltage bodies PL3 may form the driving voltage line PL extending overall in the first direction (y-axis direction).

The connection electrode 181 is electrically connected to the connection electrode 177 included in the first connection electrode layer CEL1 via a contact hole 83 penetrating the first planarization insulating layer 107. As described above, the connection electrode 177 may be electrically connected to the drain region of the light-emission control transistor T6. Therefore, the connection electrode 181 may be electrically connected to the drain region of the light-emission control transistor T6.

The second connection electrode layer CEL2 may include a metal, an alloy, a conductive metal oxide, or a transparent conductive material. In an embodiment, for example, the second connection electrode layer CEL2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The second connection electrode layer CEL2 may have a multilayer structure, and for example, the second connection electrode layer CEL2 may have a two-layer structure of Ti/Al or a three-layer structure of Ti/Al/Ti.

A second planarization insulating layer 108 (see FIG. 15) may cover the second connection electrode layer CEL2 and may be disposed on the first planarization insulating layer 107. The second planarization insulating layer 108 may include an organic insulating material. In an embodiment, for example, the second planarization insulating layer 108 may include photoresist, benzocyclobutene (BCB), polyimide, hexamethyldisiloxane (HMDSO), polymethylmethacrylate (PMMA), polystyrene, polymer derivatives with phenolic groups, acrylic polymers, imide polymers, aryl ether-based polymers, amide-based polymers, fluorine-based polymers, p-xylene-based polymers, vinyl alcohol-based polymers, or a mixture thereof.

A pixel electrode layer PXEL, as shown in FIGS. 14 and 15, may be disposed on the second planarization insulating layer 108. The pixel electrode layer PXEL may include (or define) a plurality of pixel electrodes. FIG. 14 shows a pixel electrode PE1 of the first pixel PX1, a pixel electrode PE2 of the second pixel PX2, and a pixel electrode PE3 of the third pixel PX3. Each of the pixel electrodes PE1, PE2, and PE3 may include a first region corresponding to an emission region, and a second region surrounding the first region.

The pixel electrode PE1 is electrically connected to the connection electrode 181 included in the second connection electrode layer CEL2 via a contact hole 91 defined in the second planarization insulating layer 108. Accordingly, the pixel electrode PE1 may be electrically connected to the driving transistor T1 via the connection electrode 181 and the light-emission control transistor T6. The contact hole 91 may be arranged to correspond to the second region of the pixel electrode PE1.

A pixel-defining film 109 may be disposed on the second planarization insulating layer 108 to cover an edge of the pixel electrode PE1. The pixel-defining film 109 serves to define a pixel by having an opening corresponding to the emission region of each pixel. For reference, in FIG. 15, due to the location of the cross-sectional view, the opening of the pixel-defining film 109 is not shown. An emission layer is arranged in the opening in the pixel-defining film 109, and a common electrode CAT may be disposed on the emission layer. The pixel electrode PE1, the emission layer, and the common electrode CAT may constitute an organic light-emitting diode. The common electrode CAT may be a single body throughout a plurality of organic light-emitting diodes, and thus may correspond to the plurality of pixel electrodes. For reference, at least one functional layer such as a hole injection layer (HIL), a hole transport layer (HTL), and/or an electron injection layer (EIL) may be further arranged between the emission layer and the pixel electrode PE1 and/or the emission layer and the common electrode CAT. Such a functional layer may also be arranged between the pixel-defining film 109 and the common electrode CAT. In FIG. 15, such functional layers are not shown for convenience of illustration.

FIG. 16 is a conceptual view schematically showing a connection relationship between wires included in the display apparatus of FIG. 1. As shown in FIG. 16, in an embodiment, each of first initialization voltage lines VIL which are wires extending in the second direction (x-axis direction) may be electrically connected to a plurality of dummy clock lines DCKL1. Accordingly, in the display apparatus, the first initialization voltage lines VIL and the plurality of dummy clock lines DCKL1 may have an overall mesh structure. Accordingly, in the display region DA, voltage drop (IR drop) of the first initialization voltage Vint in the first initialization voltage lines VIL electrically connected to the first initialization transistor T4 may be effectively prevented or substantially minimized. For reference, considering this connection relationship, it may be understood that a dummy clock line DCKL1 is electrically connected to a pixel circuit. In detail, it may be understood that the dummy clock line DCKL1 may be electrically connected to the first initialization transistor T4 of the pixel circuit.

For reference, as described above, dummy scan drivers DSD include dummy clock lines DCKL1, and the scan driver layer SDL including the dummy scan driver DSD is interposed between the substrate 100 and the display layer DISL. Therefore, the first initialization voltage line VIL extending in the second direction (x-axis direction), as shown in FIG. 8, may be electrically connected to the dummy clock line DCKL1 disposed under the first initialization voltage line VIL via a contact hole, etc. In an embodiment, for example, at a portion of the first initialization voltage line VIL where the width in the first direction (y-axis direction) is relatively large, the first initialization voltage line VIL may be electrically connected to the dummy clock line DCKL1 disposed under the portion.

In such an embodiment, the display layer DISL includes a display element and a pixel circuit electrically connected to the display element, and a dummy clock line included in the scan driver layer SDL may be electrically connected to the pixel circuit.

In an embodiment, as shown in FIG. 8, the first pixel region PXA1 and the second pixel region PXA2 may be adjacent to each other in the second direction (x-axis direction). In such an embodiment, when viewed in a direction perpendicular to the substrate 100, first pixel regions PXA1 located in the first direction (y-axis direction) may overlap the first scan driver SD1, and second pixel regions PXA2 may overlap the dummy scan driver DSD. In an embodiment, where display elements in the second pixel regions PXA2 are referred to as first display elements and pixel circuits electrically connected to the first display elements are referred to as first pixel circuits, the first pixel circuits may overlap the dummy scan driver DSD disposed under the first pixel circuits. In an embodiment, where display elements in the first pixel regions PXA1 are referred to as second display elements and pixel circuits electrically connected to the second display elements are referred to as second pixel circuits, the second pixel circuits may overlap the first scan driver SD1 disposed under the second pixel circuits.

In such an embodiment, the first initialization voltage lines VIL of the first pixel circuits located in the second pixel regions PXA2, extending in the second direction (x-axis direction) and arranged in the first direction (y-axis direction), may be electrically connected to the dummy clock line DCKL1 disposed under the first initialization voltage lines VIL. The first clock line CKL1 and/or the second clock line (not shown), included in the first scan driver SD1, as shown in FIG. 16, is disposed under the first pixel region PXA1, and the dummy clock line DCKL1 is not disposed under the first pixel region PXA1. Therefore, the first initialization voltage lines VIL of the second pixel circuits located in the first pixel regions PXA1, extending in the second direction (x-axis direction) and arranged in the first direction (y-axis direction), may be electrically connected to the dummy clock line DCKL1 via the first initialization voltage lines VIL of the first pixel circuits located in the second pixel regions PXA2, extending in the second direction (x-axis direction) and arranged in the first direction (y-axis direction). For reference, the first initialization voltage lines VIL of the second pixel circuit located in the first pixel region PXA1 extend in the second direction (x-axis direction) and are arranged in the first direction (y-axis direction), as shown in FIG. 8. Each of the first initialization voltage lines VIL of the second pixel circuit located in the first pixel region PXA1 may be integrally formed as a single unitary indivisible body with a corresponding one of the first initialization voltage lines VIL of the first pixel circuit located in the second pixel region PXA2, which extend in the second direction (x-axis direction) and are arranged in the first direction (y-axis direction).

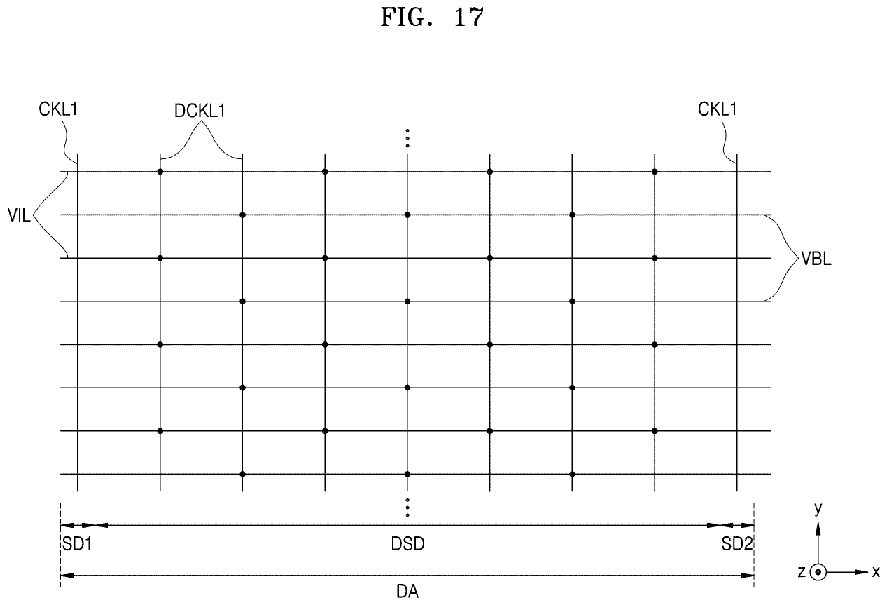

FIG. 17 is a conceptual view schematically showing a connection relationship between wires included in a display apparatus according to an embodiment. As shown in FIG. 17, in an embodiment, each of bias voltage lines VBL which are wires extending in the second direction (x-axis direction) and arranged in the first direction (y-axis direction) may be electrically connected to a plurality of dummy clock lines DCKL1. Accordingly, in the display apparatus, the bias voltage lines VBL and the plurality of dummy clock lines DCKL1 may have an overall mesh structure. Accordingly, in the display region DA, voltage drop (IR drop) of the bias voltage VOBS in the bias voltage lines VBL electrically connected to the bias transistor T7 may be effectively prevented or substantially minimized. For reference, considering this connection relationship, it may be understood that a dummy clock line DCKL1 is electrically connected to a pixel circuit. In detail, it may be understood that the dummy clock line DCKL1 is electrically connected to the bias transistor T7 of the pixel circuit.

For reference, as described above, dummy scan drivers DSD include dummy clock lines DCKL1, and the scan driver layer SDL including the dummy scan driver DSD is interposed between the substrate 100 and the display layer DISL. Therefore, the bias voltage line VBL, as shown in FIG. 11, may be electrically connected to the dummy clock line DCKL1 disposed under the bias voltage line VBL via a contact hole, etc. In an embodiment, for example, as shown in FIG. 11, the bias voltage line VBL extending in the second direction (x-axis direction) may have a portion protruding in the first direction (y-axis direction), and the protruding portion may be electrically connected to the dummy clock line DCKL1 disposed under the protruding portion.

In such an embodiment, the display layer DISL includes a display element and a pixel circuit electrically connected to the display element, and a dummy clock line included in the scan driver layer SDL may be electrically connected to the pixel circuit.

In an embodiment, as shown in FIG. 11, the first pixel region PXA1 and the second pixel region PXA2 are adjacent to each other in the second direction (x-axis direction). In such an embodiment, when viewed in a direction perpendicular to the substrate 100, the first pixel region PXA1 may overlap the first scan driver SD1, and the second pixel region PXA2 may overlap the dummy scan driver DSD. In an embodiment, where display elements in the second pixel regions PXA2 are referred to as first display elements and pixel circuits electrically connected to the first display elements are referred to as first pixel circuits, the first pixel circuits may overlap the dummy scan driver DSD disposed under the first pixel circuits. In an embodiment, where display elements in the first pixel regions PXA1 are referred to as second display elements and pixel circuits electrically connected to the second display elements are referred to as second pixel circuits, the second pixel circuits may overlap the first scan driver SD1 disposed under the second pixel circuits.

In such an embodiment, the bias voltage lines VBL of the first pixel circuits located in the second pixel regions PXA2, extending in the second direction (x-axis direction) and arranged in the first direction (y-axis direction), may be electrically connected to the dummy clock lines DCKL1 disposed under the bias voltage lines VBL. The first clock line CKL1 and/or the second clock line (not shown), included in the first scan driver SD1, as shown in FIG. 17, is disposed under the first pixel regions PXA1, and the dummy clock line DCKL1 is not disposed under the first pixel regions PXA1. Therefore, the bias voltage lines VBL of the second pixel circuits located in the first pixel regions PXA1, extending in the second direction (x-axis direction) and arranged in the first direction (y-axis direction), may be electrically connected to the dummy clock lines DCKL1 of the first pixel circuits located in the second pixel regions PXA2 via the bias voltage lines VBL extending in the second direction (x-axis direction). For reference, the bias voltage lines VBL of the second pixel circuit located in the first pixel region PXA1 extend in the second direction (x-axis direction) and are arranged in the first direction (y-axis direction), as shown in FIG. 11. Each of the bias voltage lines VBL of the second pixel circuit located in the first pixel region PXA1 may be integrally formed as a single unitary indivisible body with a corresponding one of the bias voltage lines VBL of the first pixel circuit located in the second pixel region PXA2, which extend in the second direction (x-axis direction) and are arranged in the first direction (y-axis direction).

For reference, when the first initialization voltage lines VIL are electrically connected to the dummy clock lines DCKL1 and the bias voltage lines VBL are also electrically connected to the dummy clock lines DCKL1, it may be desired to prevent the first initialization voltage lines VIL and the bias voltage lines VBL from being short-circuited. Accordingly, in an embodiment, as shown in FIG. 17, the first initialization voltage lines VIL may be electrically connected to some of the dummy clock lines DCKL1, and the bias voltage lines VBL may be electrically connected to some others of the dummy clock lines DCKL1.

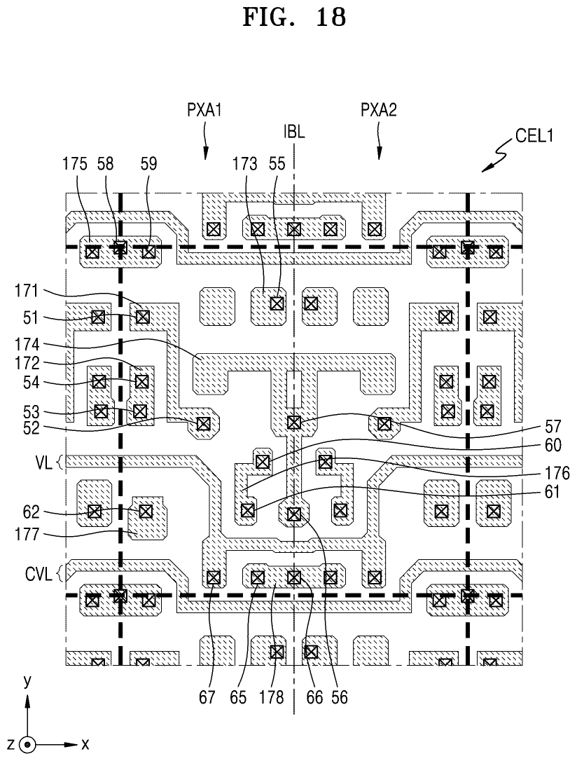

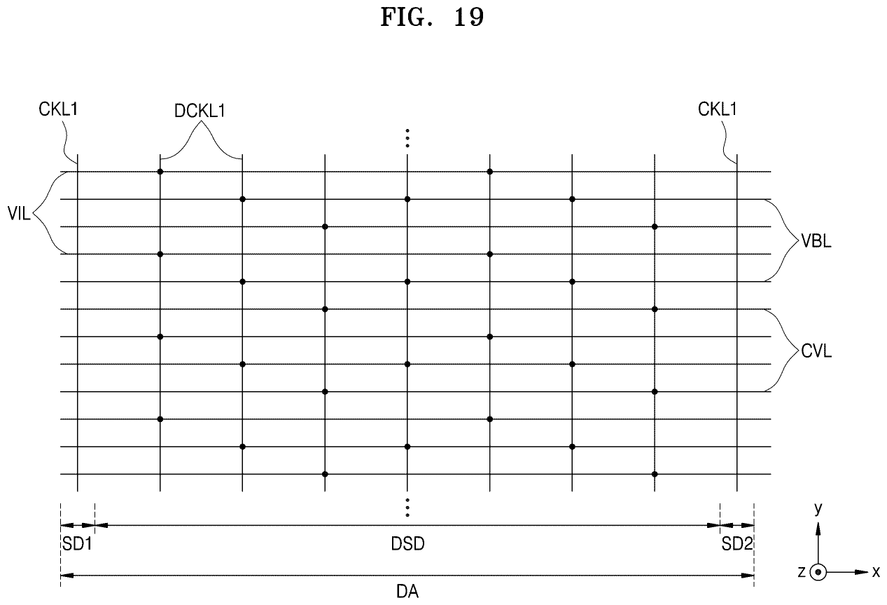

FIG. 18 is a plan view schematically showing one layer included in a display apparatus according to an embodiment, and FIG. 19 is a conceptual view schematically showing a connection relationship between wires included in the display apparatus of FIG. 18. The embodiment of the display apparatus shown in FIG. 18 is substantially the same as the embodiment of the display apparatus described above with reference to FIG. 12 except that the first connection electrode layer CEL1 further includes a common voltage line CVL. The common voltage line CVL may have a shape extending approximately in the second direction (x-axis direction).

The common electrode CAT, which is integrally formed as a single unitary indivisible body throughout a plurality of organic light-emitting elements, may be electrically connected to the common voltage line CVL. In such an embodiment, a through hole is defined or formed in the first planarization insulating layer 107, the second planarization insulating layer 108, and/or the pixel-defining film 109, over the common voltage line CVL, and thus, the common electrode CAT may be electrically connected to the common voltage line CVL. The common electrode CAT may be in direct contact with the common voltage line CVL, or the common electrode CAT and the common voltage line CVL may be electrically connected indirectly via conductive layers therebetween.

In such an embodiment, common voltage lines CVL having a shape extending in the second direction (x-axis direction) may be arranged in the first direction (y-axis direction). In addition, each of the common voltage lines CVL may be electrically connected to a plurality of dummy clock lines DCKL1. Accordingly, in the display apparatus, the common voltage lines CVL and the plurality of dummy clock lines DCKL1 may have an overall mesh structure. Accordingly, in the display region DA, voltage drop (IR drop) of the electrode voltage ELVSS in the common voltage lines CVL electrically connected to the common electrode CAT may be effectively prevented or substantially minimized. For reference, considering this connection relationship, it may be understood that the dummy clock line DCKL1 is electrically connected to the common electrode CAT.

In an embodiment, as shown in FIG. 19, first initialization voltage lines VIL may be electrically connected to the dummy clock lines DCKL1, bias voltage lines VBL may also be electrically connected to the dummy clock lines DCKL1, and the common voltage lines CVL may also be electrically connected to the dummy clock lines DCKL1. In such an embodiment, it may be desired to prevent the first initialization voltage lines VIL, the bias voltage lines VBL, and the common voltage lines CVL from being short-circuited. In such an embodiment, as shown in FIG. 19, the first initialization voltage lines VIL may be electrically connected to a first group of the dummy clock lines DCKL1, the bias voltage lines VBL may be electrically connected to a second group of the dummy clock lines DCKL1, and the common voltage lines CVL may be electrically connected to a third group of the dummy clock lines DCKL1.

For reference, in order to form such a mesh structure, it may be considered that the first connection electrode layer CEL1 or the second connection electrode layer CEL2 has a wire extending in the first direction (y-axis direction) and connects the wire to the first initialization voltage lines VIL, bias voltage lines VBL, or the common voltage lines CVL. However, in this case, the area or width of another connection electrode or wire present in the first connection electrode layer CEL1 or the second connection electrode layer CEL2 is inevitably reduced, and thus, for example, a voltage drop may occur in the driving voltage line PL that supplies the power voltage ELVDD. In a case, where the first connection electrode layer CEL1 or the second connection electrode layer CEL2 has a wire extending in the first direction (y-axis direction), there is inevitably a limit to the area or position of the upper electrode of the storage capacitor Cst to prevent parasitic capacitance from occurring between the wire and the upper electrode of the storage capacitor Cst. The display apparatus according to an embodiment employs a dummy clock line included in a dummy scan driver disposed under the display layer, and thus, such problems may be effectively prevented from occurring.

According to an embodiment of the disclosure as described above, it is possible to implement a display apparatus with a peripheral region having a reduced area and is capable of displaying high-quality images. However, the scope of the disclosure is not limited thereto.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a substrate including a display region and a peripheral region outside the display region;
a display layer on the substrate; and
a scan driver layer interposed between the substrate and the display layer,
wherein, when viewed in a direction perpendicular to the substrate, the scan driver layer comprises a scan driver which is located within a side portion of the display region next to an edge of the display region, and a dummy scan driver which is located at a center portion of the display region, and
the dummy scan driver comprises a dummy clock line extending in a first direction.

2. The display apparatus of claim 1, wherein the scan driver extends in the first direction.

3. The display apparatus of claim 1, wherein the display layer comprises a first display element and a first pixel circuit electrically connected to the first display element, and
the dummy clock line is electrically connected to the first pixel circuit.

4. The display apparatus of claim 1, wherein the display layer comprises a first display element disposed over the dummy scan driver, and a first pixel circuit electrically connected to the first display element,
the first pixel circuit comprises a first wire extending in a second direction crossing the first direction, and
the first wire is electrically connected to the dummy clock line.

5. The display apparatus of claim 4, wherein the first wire and the dummy clock line are electrically connected to a common electrode of the first display element.

6. The display apparatus of claim 4, wherein the first wire and the dummy clock line are electrically connected to an initialization transistor of the first pixel circuit.

7. The display apparatus of claim 4, wherein the first wire and the dummy clock line are electrically connected to a bias transistor of the first pixel circuit.

8. The display apparatus of claim 4, wherein the display layer comprises a second display element disposed over the scan driver, and a second pixel circuit electrically connected to the second display element,
the second pixel circuit comprises a second wire extending in the second direction, and
the second wire is electrically connected to the first wire.

9. The display apparatus of claim 8, wherein the second wire and the first wire are integrally formed as a single unitary indivisible body.

10. A display apparatus comprising:
a substrate including a display region and a peripheral region outside the display region;
a display layer on the substrate; and
a scan driver layer interposed between the substrate and the display layer,
wherein, when viewed in a direction perpendicular to the substrate, the scan driver layer comprises a scan driver which is located within a side portion of the display region next to an edge of the display region, and dummy scan drivers which are located at a center portion of the display region, and
the dummy scan drivers comprise dummy clock lines extending in a first direction.

11. The display apparatus of claim 10, wherein the scan driver extends in the first direction.

12. The display apparatus of claim 10, wherein the display layer comprises first display elements and first pixel circuits electrically connected to the first display elements, respectively, and
the dummy clock lines are electrically connected to the first pixel circuits.

13. The display apparatus of claim 10, wherein the display layer comprises first display elements disposed over the dummy scan drivers, and first pixel circuits electrically connected to the first display elements, respectively,
the first pixel circuits comprise first wires extending in a second direction crossing the first direction and arranged in the first direction, and
the first wires are electrically connected to the dummy clock lines.

14. The display apparatus of claim 13, wherein each of the first wires is electrically connected to the dummy clock lines.

15. The display apparatus of claim 13, wherein the first wires and the dummy clock lines are electrically connected to a common electrode of the first display elements.

16. The display apparatus of claim 13, wherein the first wires and the dummy clock lines are electrically connected to initialization transistors of the first pixel circuits.

17. The display apparatus of claim 13, wherein the first wires and the dummy clock lines are electrically connected to bias transistors of the first pixel circuits.

18. The display apparatus of claim 13, wherein the display layer comprises second display elements disposed over the scan driver, and second pixel circuits electrically connected to the second display elements, respectively,
the second pixel circuits comprise second wires extending in the second direction and arranged in the first direction, and
each of the second wires is electrically connected to a corresponding one of the first wires.

19. The display apparatus of claim 18, wherein each of the second wires and the corresponding one of the first wires are integrally formed as a single unitary indivisible body.

20. The display apparatus of claim 10, wherein the display layer comprises first display elements disposed over the dummy scan drivers, and first pixel circuits electrically connected to the first display elements, respectively,
the first pixel circuits comprise first first wires extending in a second direction crossing the first direction and arranged in the first direction, and second first wires extending in the second direction and arranged in the first direction,
the first first wires are electrically connected to a first group of the dummy clock lines, and
the second first wires are electrically connected to a second group of the dummy clock lines.

21. The display apparatus of claim 20, wherein the first first wires are electrically connected to initialization transistors of the first pixel circuits, and the second first wires are electrically connected to bias transistors of the first pixel circuits.

22. An electronic apparatus including the display apparatus of claim 1.

23. The electronic apparatus of claim 22, wherein the electronic apparatus is at least one of a smartphone, a mobile phone, a navigation device, a game device, a television (TV), a vehicle head unit, a notebook computer, a laptop computer, a tablet computer, a personal media player (PMP), or a personal digital assistant (PDA).

24. An electronic apparatus including the display apparatus of claim 10.

25. The electronic apparatus of claim 24, wherein the electronic apparatus is at least one of a smartphone, a mobile phone, a navigation device, a game device, a television (TV), a vehicle head unit, a notebook computer, a laptop computer, a tablet computer, a personal media player (PMP), or a personal digital assistant (PDA).
